(19) United States
(12) Patent Application Publication
(10) Pub. No.: US 2018/0276321 A1
(43) Pub. Date: Sep. 27, 2018

(54) METHOD AND APPARATUS FOR TESTING DESIGN OF SATELLITE WIRING HARNESS AND SIGNAL PROCESSING UNITS

(71) Applicant: THE BOEING COMPANY, CHICAGO, IL (US)

(72) Inventors: Villy Angelico, El Segundo, CA (US); Timothy J. Dale, Berkeley, MO (US); Thanh P. Duong, Anaheim, CA (US); John L. Henroid, St. Louis, MO (US); Adeel Khan, Saint Charles, MO (US); Randall J. Krohn, Berkeley, MO (US); Roland Mah, El Segundo, CA (US); Jill McLean, Whitesboro, NY (US); Bradley J. Trapp, Berkeley, MO (US)

(21) Appl. No.: 15/469,137

(22) Filed: Mar. 24, 2017

(51) Int. Cl. G06F 17/50; G01R 31/28

(52) U.S. Cl. CPC G06F 17/509; G01R 31/008; G01R 31/2848

(57) ABSTRACT

A method of testing designs of wiring harnesses includes generating a virtual electrical system including virtual wiring harnesses that interconnect virtual modules of communications circuitry including signal sources and signal destinations. The method also includes testing signal pathways and thereby the virtual wiring harnesses. The testing includes generating a simulated signal that is input to a specific electrical connection at a signal source and routed through a signal pathway to a specific electrical connection to a signal destination. The testing includes verifying receipt of the simulated signal by the specific electrical connections via the signal pathway. And in an instance in which receipt is not verified, the testing includes identifying a particular electrical connection at which an error occurred in the receipt of the simulated signal, and a particular virtual wiring harness and a particular virtual module respectively connected to and including the particular electrical connection.

### TECHNOLOGICAL FIELD

The present disclosure relates generally to satellite communications systems and, in particular, to satellite design and manufacturing.

### BACKGROUND

Satellites are used in a variety of diverse fields such as for navigation, communication, environmental monitoring, weather forecasting, broadcasting and the like. Many homes, businesses, government organizations and other users may use satellites on a daily basis for entertainment, communication, information gathering and other purposes. Hundreds of man-made satellites now orbit the earth, and more are launched each year.

A typical modern satellite may include a metal or composite frame that carries one or more antennas, power sources such as solar cells and batteries, and various electronic components including modules of communications circuitry implemented by satellite payload transponders. These modules are numerous and may include telemetry and command modules, and modules of radio frequency (RF) communications circuitry including telemetry and command functionality that are respectively monitored and commanded by the telemetry modules and command modules. The telemetry and command modules are often connected to the modules of RF communications circuitry by wiring harnesses, and modules of RF communications circuitry are often interconnected by RF links.

The design and manufacture of a satellite often includes payload design, and a payload test program to validate and verify the payload design. Payload design currently includes calculation of integrated payload performance predictions based on unit design performance predictions. The nature of predictions forces payload engineers to design in conservatism to ensure actual end item performance. This conservatism has often forced the satellite to be larger than needed for power, size, weight, and unit redundancy—all of which are direct cost drivers to the overall program costs and affordability.

In order to define a payload test program, there needs to be a design. During proposal or even program baseline, the design is more conceptual with numerous assumptions on the design results. Because of the lack of design definition, the test program is based on assumptions that are not valid resulting in unidentified impacts to testability, test complexity, test scope, test software and Special Test Equipment (STE) capability. This is a direct source of recurring cost and schedule overruns on programs.

For wiring harnesses, the harness design to build engineering translation is not currently validated, and is instead assumed to be correct. Harness design errors often discovered during spacecraft integration and systems test causing harness rework, retesting, and impacting program schedule and cost baselines. It is a challenge to complete the harness interface audit before spacecraft systems test due to the satellite systems engineering database (SSED) not being available, and due to the intensive manual effort exceeding the allocated time before spacecraft systems test.

Therefore it would be desirable to have a system and method that takes into account at least some of the issues discussed above, as well as other possible issues.

### BRIEF SUMMARY

Some example implementations of the present disclosure provide a system, and corresponding method and computer-readable storage medium for testing designs of wiring harnesses such as those designed for a satellite. In some example implementations, satellite test procedures are executed via integrated virtual modules of communications circuitry including telemetry and command modules, virtual wiring harnesses, and a suite of test cases to traverse the harness paths and validate that commands sent and telemetry received are sourced and received by the correct modules. Example implementations address one objective by validating the harness design engineering, the harness manufacturing engineering, the satellite database and the test procedures together as they are actually implemented to translate between design and build. And example implementations address another objective by automating a manual intensive process and enabling the harness interface audit to be completed before spacecraft systems test as intended.

Some example implementations provide a method of testing designs of wiring harnesses, the method comprising executing a modeling application to generate a virtual electrical system including virtual wiring harnesses that interconnect virtual modules of communications circuitry including telemetry and command modules, the virtual wiring harnesses having functionality equivalent to that of the designs of wiring harnesses, the virtual modules having signal sources, signal destinations and redistribution points therebetween, the virtual modules also having electrical connections to the signal sources, signal destinations and redistribution points, and the virtual wiring harnesses being connected to the electrical connections and thereby forming signal pathways through the virtual electrical system including at least the telemetry and command modules, each signal pathway being defined by respective electrical connections to a signal source, signal destination and any redistribution point therebetween, and by at least one of the virtual wiring harnesses connected to the respective electrical connections; and executing a testing application to test the signal pathways and thereby the virtual wiring harnesses, including for each signal pathway having thereon specific electrical connections to a signal source, signal destination and any redistribution point therebetween, the testing application at least: generating a simulated signal that is input to the specific electrical connection at the signal source and routed through the signal pathway to the specific electrical connection to the signal destination; verifying receipt of the simulated signal by the specific electrical connections via the signal pathway; and in an instance in which receipt of the simulated signal is not verified, identifying a particular electrical connection of the specific electrical connections at which an error occurred in the receipt of the simulated signal, and identifying a particular virtual wiring harness and a particular virtual module respectively connected to and including the particular electrical connection, and wherein the testing application is executed to further generate a displayable output that identifies for each error, the particular electrical connection at which the error occurred, and the particular virtual wiring harness and the particular virtual module respectively connected to and including the particular electrical connection.

In some example implementations of the method of any preceding or any subsequent example implementation, or any combination thereof, the virtual modules include a virtual module with a redistribution point embodied as a switch with multiple inputs and a single output, each of the multiple inputs to the single output being on a separate one of the signal pathways.

In some example implementations of the method of any preceding or any subsequent example implementation, or any combination thereof, the virtual modules include a virtual module with a redistribution point embodied as a switch with a single input and multiple outputs, the signal input to each of the multiple outputs being on a separate one of the signal pathways.

In some example implementations of the method of any preceding or any subsequent example implementation, or any combination thereof, executing the testing application to generate the displayable output includes executing the testing application to generate the displayable output that further includes for each error, routing data for the simulated signal that identifies one or more of the specific electrical connections at which the receipt of the simulated signal is verified, and the particular electrical connection at which the receipt of the simulated signal is not verified.

In some example implementations of the method of any preceding or any subsequent example implementation, or any combination thereof, when the receipt of the simulated signal is not verified, the method further comprises re-executing the modeling application to generate a modified virtual electrical system in which the particular virtual wiring harness has functionality equivalent to a modified design that corrects the error; and re-executing the testing application to test the signal pathways through the modified virtual electrical system.

In some example implementations of the method of any preceding or any subsequent example implementation, or any combination thereof, executing the testing application includes executing the testing application to further transmit the displayable output to a visualization tool configured to display the virtual electrical system and identify thereon the particular electrical connection at which the error occurred, and the particular virtual wiring harness and the particular virtual module respectively connected to and including the particular electrical connection.

In some example implementations of the method of any preceding or any subsequent example implementation, or any combination thereof, executing the testing application includes executing the testing application to generate the displayable output that in an instance in which receipt of the simulated signal by the specific electrical connections is verified, indicates the designs of wiring harnesses are validated for production of the wiring harnesses based thereon.

Some example implementations provide an apparatus for testing designs of wiring harnesses. The apparatus comprises a processor and a memory storing executable instructions that, in response to execution by the processor, cause the apparatus to at least perform the method of any preceding example implementation, or any combination thereof.

Some example implementations provide a computer readable storage medium for testing designs of wiring harnesses. The computer-readable storage medium is non-transitory and having computer-readable program code portions stored therein that, in response to execution by a processor, cause an apparatus to at least perform the method of any preceding example implementation, or any combination thereof.

These and other features, aspects, and advantages of the present disclosure will be apparent from a reading of the following detailed description together with the accompanying drawings, which are briefly described below. The present disclosure includes any combination of two, three, four or more features or elements set forth in this disclosure, regardless of whether such features or elements are expressly combined or otherwise recited in a specific example implementation described herein. This disclosure is intended to be read holistically such that any separable features or elements of the disclosure, in any of its aspects and example implementations, should be viewed as combinable, unless the context of the disclosure clearly dictates otherwise.

It will therefore be appreciated that this Brief Summary is provided merely for purposes of summarizing some example implementations so as to provide a basic understanding of some aspects of the disclosure. Accordingly, it will be appreciated that the above described example implementations are merely examples and should not be construed to narrow the scope or spirit of the disclosure in any way. Other example implementations, aspects and advantages will become apparent from the following detailed description taken in conjunction with the accompanying drawings which illustrate, by way of example, the principles of some described example implementations.

### BRIEF DESCRIPTION OF THE DRAWING(S)

Having thus described example implementations of the disclosure in general terms, reference will now be made to the accompanying drawings, which are not necessarily drawn to scale, and wherein:

FIG. 1 illustrates a system according to example implementations of the present disclosure;

FIG. 2 illustrates a wiring harness subsystem of the system of FIG. 1, according to some example implementations;

FIG. 3 illustrates an example of a suitable virtual electrical system generated by a modeling application of the wiring harness subsystem of FIG. 2, according to example implementations;

FIG. 4 illustrates an example implementation of the wiring harness subsystem of FIG. 2 in the form of a harness validation tool, according to example implementations;

FIGS. 5, 6 and 7 illustrate example directed graphs according to example implementations;

FIG. 8 is an example of the content of a harness traversal output file according to example implementations;

FIG. 9 is a flowchart illustrating various steps in a method of testing designs of wiring harnesses, according to various example implementations; and

FIG. 10 illustrates an apparatus according to some example implementations.

### DETAILED DESCRIPTION

Some implementations of the present disclosure will now be described more fully hereinafter with reference to the accompanying drawings, in which some, but not all implementations of the disclosure are shown. Indeed, various implementations of the disclosure may be embodied in many different forms and should not be construed as limited to the implementations set forth herein; rather, these example implementations are provided so that this disclosure will be thorough and complete, and will fully convey the scope of the disclosure to those skilled in the art. For example, unless otherwise indicated, reference to something as being a first, second or the like should not be construed to imply a particular order. Also, for example, reference may be made herein to quantitative measures, values, relationships or the like (e.g., planar, coplanar, perpendicular). Unless otherwise stated, any one or more if not all of these may be absolute or approximate to account for acceptable variations that may occur, such as those due to engineering tolerances or the like. Like reference numerals refer to like elements throughout.

Example implementations of the present disclosure are directed to testing designs of communications circuitry such as a design of a satellite payload transponder with modules of radio frequency (RF) communications circuitry including telemetry and command functionality, and testing designs of wiring harnesses such as those designed for a satellite.

Satellites and a number of other complex electrical and electromechanical systems are composed of electronics including modules of communications circuitry implemented by the satellite design. These modules are numerous and may include telemetry and command modules and the like, and modules of RF communications circuitry including telemetry and command functionality that are respectively monitored and commanded by the telemetry modules and command modules. Examples of suitable telemetry and command modules include remote telemetry and command unit (RTCU), embedded telemetry module (ETM), embedded command module (ECM), central telemetry and command unit (CTCU) and the like. The telemetry and command modules are often connected to the modules of RF communications circuitry by wiring harnesses, and modules of RF communications circuitry are often interconnected by RF links. Example implementations of the present disclosure provide a system for testing designs of electrical, electromechanical and RF communication systems such as satellites.

FIG. 1 illustrates a system 100 according to example implementations of the present disclosure. The system is configured to perform a number of different functions or operations, either automatically, under direct operator control, or some combination of thereof. In this regard, in some examples, the system is configured to perform one or more of its functions or operations automatically, that is, without being directly controlled by an operator. Additionally or alternatively, in some examples, the system is configured to perform one or more of its functions or operations under direct operator control.

The system 100 includes one or more of each of any of a number of different subsystems (each an individual system) for performing one or more of its functions or operations. In some examples, the system includes a communications module subsystem 102 and a wiring harness subsystem 104 coupled to one another. Although being shown together as part of the system, it should be understood that either of the subsystems may function or operate as a separate system without regard to the other. And further, it should be understood that the system may include one or more additional or alternative subsystems than those shown in FIG. 1.

The communications module subsystem 102 is generally configured to test designs of communications circuitry such as a design of a satellite payload transponder with modules of RF communications circuitry including telemetry and command modules. More information regarding the communications module is provided in U.S. Patent Application No. ______, entitled: Method and Apparatus for Testing RF Performance of a Satellite Wiring Harness and Signal Processing Units, filed concurrently herewith, the content of which is incorporated herein by reference.

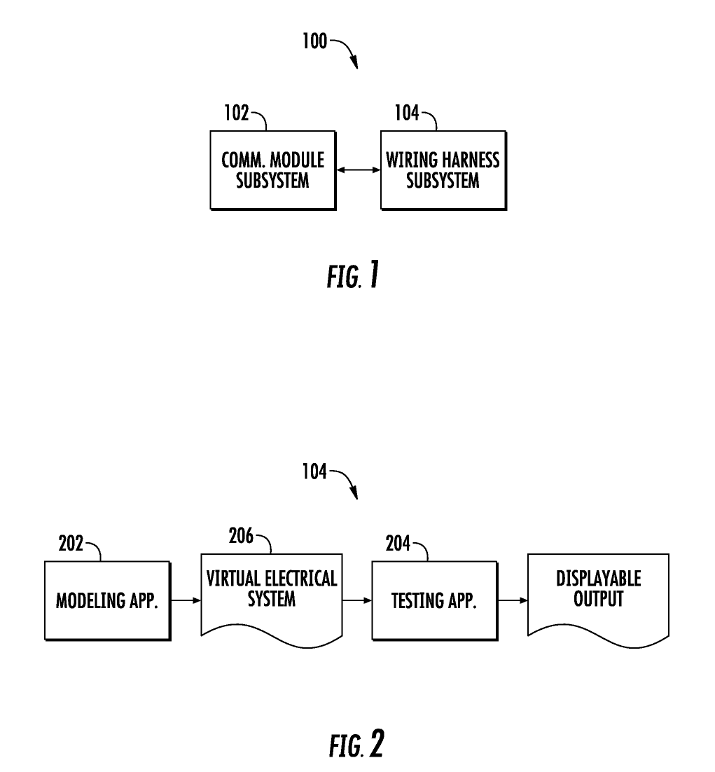

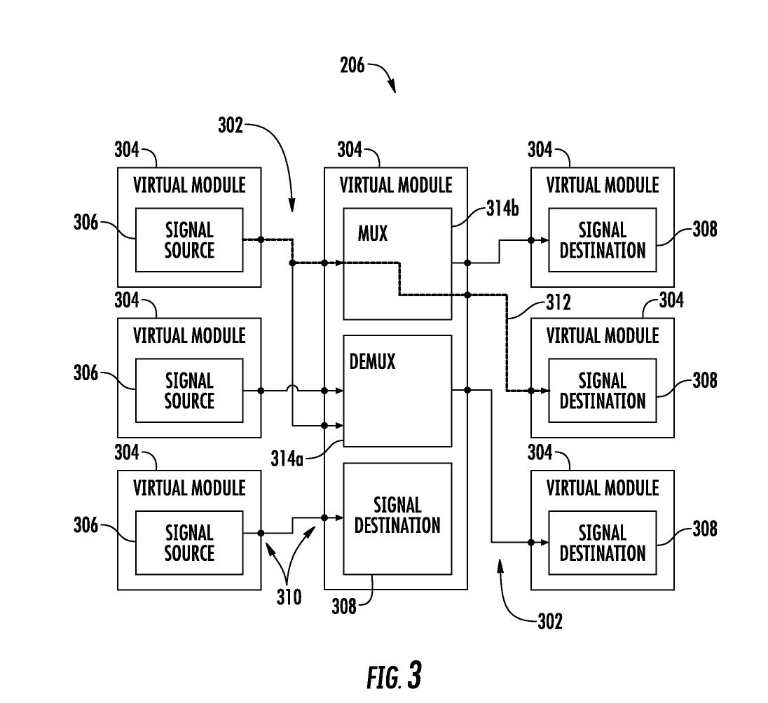

The wiring harness subsystem 104 is generally configured to test designs of wiring harnesses such as those designed for a satellite. FIG. 2 more particularly illustrates the wiring harness subsystem according to some example implementations of the present disclosure. The wiring harness subsystem includes one or more of each of any of a number of different sub-subsystems (each an individual system or subsystem) for performing one or more of its functions or operations. As shown, in some examples, the wiring harness subsystem includes a modeling application 202 and a testing application 204. Although being shown together as part of the system, it should be understood that either of the sub-subsystems may function or operate as a separate system or subsystem without regard to the other. And further, it should be understood that the wiring harness subsystem may include one or more additional or alternative sub-subsystems than those shown in FIG. 2.

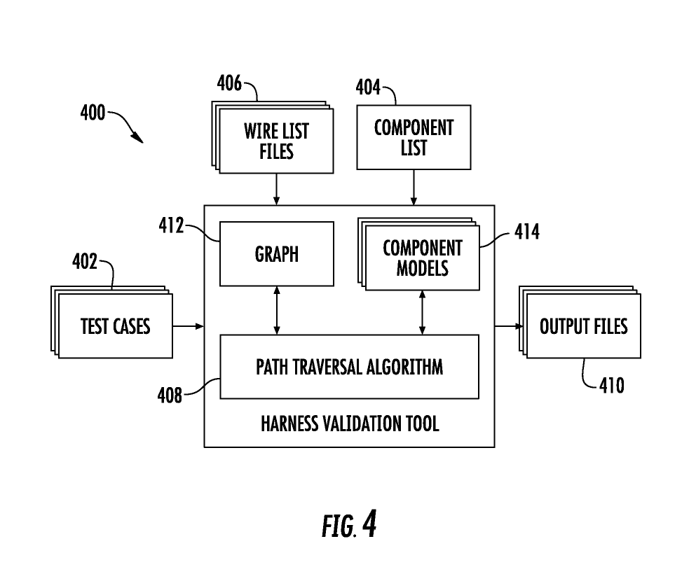

According to example implementations, the modeling application 202 is executable to generate a virtual electrical system 206. FIG. 3 illustrates an example of a suitable virtual electrical system. As shown, the virtual electrical system includes virtual wiring harnesses 302 that interconnect virtual modules 304 of communications circuitry including telemetry and command modules. As generated by the modeling application, the virtual wiring harnesses have functionality equivalent to that of the designs of wiring harnesses.

As also shown in FIG. 3, the virtual modules 304 have signal sources 306, signal destinations 308 and redistribution points therebetween. The virtual modules also have electrical connections 310 (only two of which is called out in the figure) to the signal sources, signal destinations and redistribution points. The virtual wiring harnesses are connected to the electrical connections and thereby form signal pathways 312 (one example of which is shown) through the virtual electrical system including at least the telemetry and command modules. According to example implementations, each signal pathway is defined by respective electrical connections to a signal source, signal destination and any redistribution point therebetween, and by at least one of the virtual wiring harnesses connected to the respective electrical connections.

In some examples, the virtual modules 304 include a virtual module with a redistribution point embodied as a switch such as a demultiplexer 314a with multiple inputs and a single output, with each of the multiple inputs to the single output being on a separate one of the signal pathways. Additionally or alternatively, in some examples, the virtual modules include a virtual module with a redistribution point embodied as a switch such as a multiplexer 314b with a single input and multiple outputs, with the signal input to each of the multiple outputs being on a separate one of the signal pathways.

Returning to FIG. 2, the testing application 204 is executable to test the signal pathways 312 and thereby the virtual wiring harnesses 302. This includes each signal pathway having thereon specific electrical connections 310 to a signal source 306, signal destination 308 and any redistribution point 314a, 314b therebetween. For each signal pathway, the testing application is executed to at least generate a simulated signal that is input to the specific electrical connection at the signal source (the specific electrical connection to the signal source) and routed (intended to be routed) through the signal pathway to the specific electrical connection to the signal destination.

The testing application 204 is executed to also verify receipt of the simulated signal by the specific electrical connections 310 via the signal pathway 312. In an instance in which receipt of the simulated signal is not verified, the testing application is also to identify a particular electrical connection of the specific electrical connections 310 at which an error occurred in the receipt of the simulated signal, and identify a particular virtual wiring harness 302 and a particular virtual module 304 respectively connected to and including the particular electrical connection.

As or after each signal pathway 312 is tested, the testing application 204 is to further generate a displayable output that identifies for each error, the particular electrical connection 310 at which the error occurred, and the particular virtual wiring harness 302 and the particular virtual module 304 respectively connected to and including the particular electrical connection. In some examples, the displayable output further includes for each error, routing data for the simulated signal that identifies one or more of the specific electrical connections at which the receipt of the simulated signal is verified. In some examples in which receipt of the simulated signal by the specific electrical connections is verified, the displayable output indicates the designs of wiring harnesses are validated for production of the wiring harnesses based thereon.

In some examples, the testing application 204 is to further transmit the displayable output to a visualization tool configured to display the virtual electrical system 206. In these examples, the visualization tool is configured to identify on the display of the virtual electrical system, the particular electrical connection 310 at which the error occurred, and the particular virtual wiring harness 302 and the particular virtual module 304 respectively connected to and including the particular electrical connection.

In some examples when the receipt of the simulated signal is not verified, the design of the particular virtual wiring harness 302 may be modified and the modeling and testing applications 202, 204 rerun. In these examples, the modeling application is re-executed to generate a modified virtual electrical system in which the particular virtual wiring harness has functionality equivalent to a modified design that corrects the error. And the testing application is re-executed to test the signal pathways through the modified virtual electrical system.

To further illustrate example implementations of the present disclosure, FIG. 4 illustrates an example implementation of the wiring harness subsystem 104 embodied as a harness validation tool 400 to test and validate an electrical system of hardware components including modules of communications circuitry. The inputs to the tool are a suite of test cases 402, a component file 404 detailing the list of the underlying components to be modeled, and wire list files 406 that list all wires of the wiring harness(es) that fully describe the electrical system under test. This procedure can be performed before the physical hardware components are fabricated, providing early error detection. In some examples, the individual hardware components all have unique identifiers, but multiple instances of each type of hardware component can exist. In these examples, each wire that is used to describe the electrical system also has a unique identifier, and contains both starting and ending electrical connection points. The hardware component unique identifier may be derivable from the wires starting and ending connection points.

In some examples, the suite of test cases 402 is designed with the goal of achieving full system wiring coverage. In some examples in which the electrical system is that of a satellite, the test cases may be exported from a satellite systems engineering database (SSED). Each test case is generally a representation of a signal sent through the system from a signal source. The tool 400 includes a recursive signal pathway traversal algorithm 408 that uses this signal source as a point of origin for a signal pathway through the electrical system. At the completion of each test case, the tool provides an output file 410 with details such as signal paths traversed, errors reported and components encountered. This information can be used to identify connection errors and provide test coverage to verify system wiring.

Using the wire list files 404 that describe the wiring within the hardware system, and implementing the modeling application 202, the tool 400 is configured to create a directed graph 412 that serves as a model of the electrical system under test (virtual electrical system). FIGS. 5 and 6 illustrate example directed graphs 500, 600. A vertex represents an underlying component with one or more incoming and/or outgoing connection points, and an edge represents a wire between the underlying connection points. The directed graph 500 in FIG. 5 is a basic graph with one edge per connection, whereas the directed graph 600 in FIG. 6 is a more advanced graph with multiple edges that may represent redundancy within the electrical system.

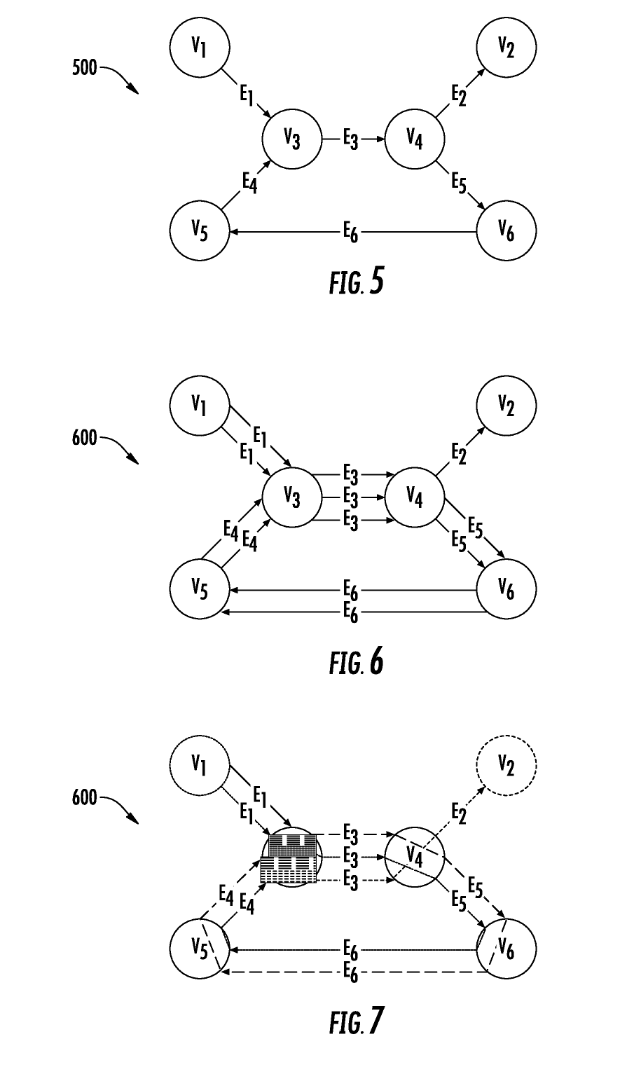

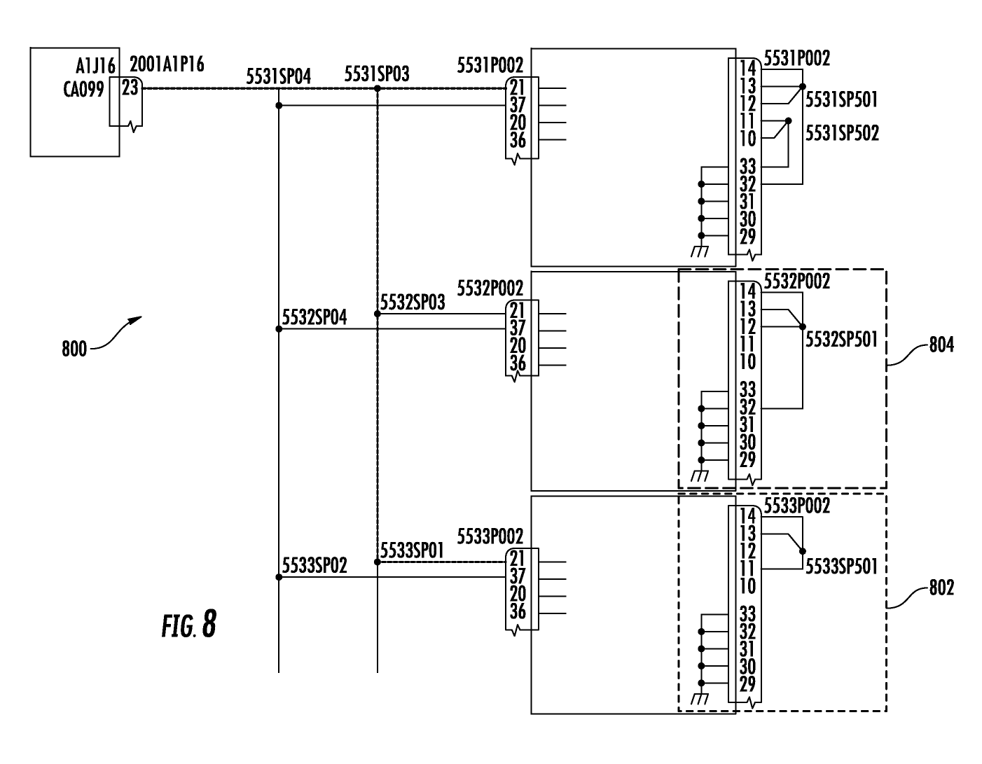

Also needed for the graph 412 to be completed is a series of virtual component models 414 that represent the hardware components (virtual modules of communications circuitry). These virtual component models are capable of adding multiple edges to the graph as well as routing input to output pins (electrical connections). The tool 400 can add logic per a component connection point as deemed necessary to provide additional component validation. FIG. 7 illustrates the directed graph 600 of FIG. 6, but with added connections with signal routing logic in the vertices representing the hardware components.

Once the graph 412 is constructed it can be used by the recursive signal pathway traversal algorithm 408 to determine all the wires that are traversed for a particular test case 402, and which may implement the testing application 204. The goal at the end of running a full suite of test cases is to determine coverage of all wires in the electrical system under test. The process of running a test case through the electrical system includes providing the tool 400 with a test case identifier that directly or indirectly references a particular hardware component and electrical connection that would transmit the signal into the physical electrical system. Using that electrical connection to a signal source as a starting location, the recursive signal pathway traversal algorithm is used to traverse every connection that is connected to the starting electrical connection.

The algorithm 408 operates by looping through every connection that is connected to the starting electrical connection. In some examples, these connections are known as level-1 connections. For each level-1 connection, the algorithm calls itself finding each electrical connection associated with that level-1 connection, which connections in some examples are known as level-2 connections. This process continues down until all electrical connections associated with the starting electrical connection have been identified and traversed.

During the process of traversing all of the identified electrical connections, the algorithm 408 will run into cases where an electrical connection has no additional electrical connections. These electrical connections are where the component input/output connection routing comes into play. Using information found in the electrical connection, a unique component identifier can be derived allowing for the specific component instance to be determined. And once the component instance is determined, the algorithm can continue through the virtual component model using its logic.

When a virtual component model 414 is created, the function of each electrical connection and how it should respond to the algorithm 408 entering on that electrical connection is known. The virtual component model can be setup to report an error, continue the traversal, stop the traversal, or any application-specific operation deemed necessary or otherwise appropriate. For example, if a component contains a selectable path (e.g., demultiplexer 314a, multiplexer 314b), the it can be modeled by either traversing all potential output paths or maintaining knowledge of the selected output path and only traversing it. If the component has been modeled to continue traversing, a set of output electrical connections that are associated with the electrical connection the algorithm arrived on is provided; otherwise, this connection would be the breakout condition for the algorithm. For each output electrical connection that is setup, the traversal continues from it. The process of traversing and entering/exiting components continues until every electrical connection that is related to the starting electrical connection has been traversed.

The algorithm 408 also maintains a record of various activities that occurred during the traversal. In some examples, these activities include electrical connections traversed, components entered/exited, errors encountered, or anything else deemed necessary or otherwise appropriate. This record is exported to an output file 410 after the completion of a test case 402. This provides a report about which test cases passed and failed, what issues were encountered during the traversal and the exact pathway that was traversed during each test case. These reports could be used to modify the wiring information based on errors encountered or to be used as proof of full coverage of wires in the system. Alternatively, these reports may be displayed to assist in debugging system wiring issues.

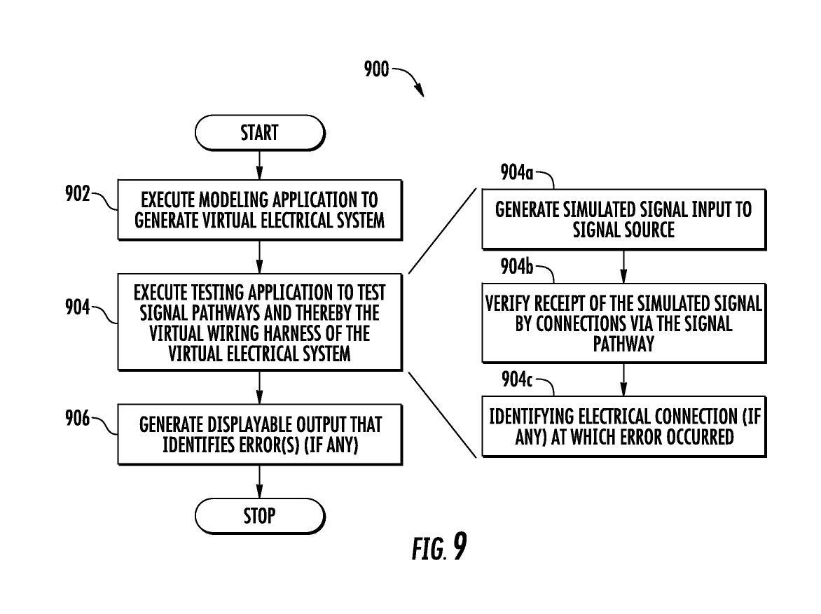

FIG. 8 is an example of displayable content 800 of a harness traversal output file 410 according to example implementations. As shown, the traversal originates from the component with electrical connector 2001A2P16-23, passed through a splice to three signal destinations. The original traversal failed at the intended signal destination (see box 802) because the address lines weren't correctly terminated with a ground (see box 804). The command was intended for the component with the red box.

Primary YYY—Primary Channel

Command: XXXX_Reset

2001A1P16-23->5531SP03-A (60338)

5531SP03-A->5531P002-21 (60301)

Entering component XXXX urd 5531 on connector 5531P002 pin 21

5531SP03-A->5532SP03-A (60340)

5532SP03-A->5532P002-21 (60303)

Entering component XXXX urd 5532 on connector 5532P002 pin 21

5532SP03-A->5533SP01-A (60342)

5533SP01-A->5533P002-21 (60305)

Entering component XXXX urd 5533 on connector 5533P002 pin 21

The design was subsequently corrected and the wire list 404 modified. The command traversal now correctly reaches the intended signal destination with the destination address bits matching the hardware address. The traversal ends with this next entry logged:

XXXX_Reset (0x6D0F) executed on XXXX (5533)

Command XXXX_Reset executed via serial interface.

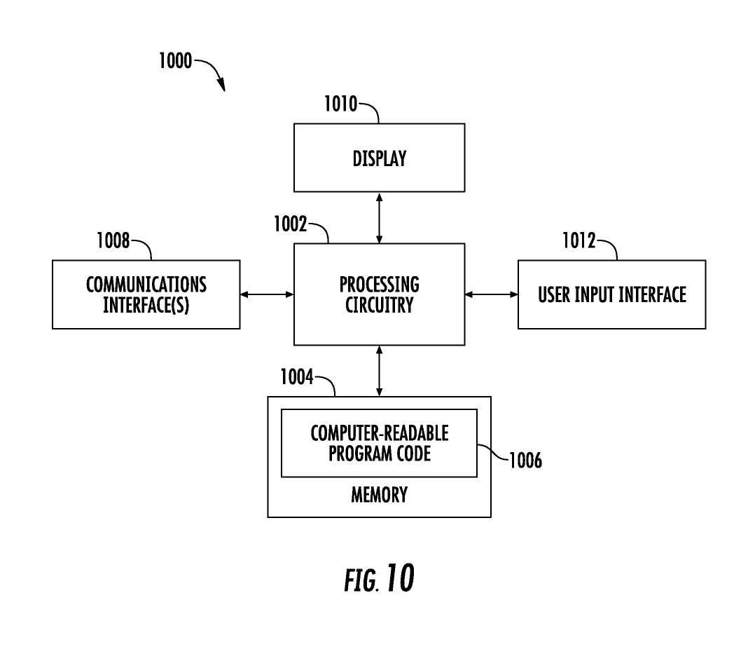

FIG. 9 is a flowchart illustrating various steps in a method 900 of testing designs of wiring harnesses. As shown at block 902, the method includes executing a modeling application to generate a virtual electrical system including virtual wiring harnesses that interconnect virtual modules of communications circuitry including telemetry and command modules. The virtual wiring harnesses have functionality equivalent to that of the designs of wiring harnesses. The virtual modules have signal sources, signal destinations and redistribution points therebetween, and the virtual modules also have electrical connections to the signal sources, signal destinations and redistribution points. The virtual wiring harnesses are connected to the electrical connections and thereby form signal pathways through the virtual electrical system including at least the telemetry and command modules. Each signal pathway is defined by respective electrical connections to a signal source, signal destination and any redistribution point therebetween, and by at least one of the virtual wiring harnesses connected to the respective electrical connections.

As shown in block 904, the method also includes executing a testing application to test the signal pathways and thereby the virtual wiring harnesses. This includes a number of sub-steps for each signal pathway having thereon specific electrical connections to a signal source, signal destination and any redistribution point therebetween. It includes the testing application generating a simulated signal that is input to the specific electrical connection at the signal source and routed through the signal pathway to the specific electrical connection to the signal destination, as shown in block 904a. It includes the testing application verifying receipt of the simulated signal by the specific electrical connections via the signal pathway, as shown in block 904b. And in an instance in which receipt of the simulated signal is not verified, it includes the testing application identifying a particular electrical connection of the specific electrical connections at which an error occurred in the receipt of the simulated signal, and identifying a particular virtual wiring harness and a particular virtual module respectively connected to and including the particular electrical connection, as shown in block 904c. The testing application is also executed to further generate a displayable output that identifies for each error, the particular electrical connection at which the error occurred, and the particular virtual wiring harness and the particular virtual module respectively connected to and including the particular electrical connection, as shown in block 906.

According to example implementations of the present disclosure, the system 100 and its subsystems including the communications module subsystem 102 and the wiring harness subsystem 104 may be implemented by various means. Means for implementing the system and its subsystems may include hardware, alone or under direction of one or more computer programs from a computer-readable storage medium. In some examples, one or more apparatuses may be configured to function as or otherwise implement the system and its subsystems shown and described herein. In examples involving more than one apparatus, the respective apparatuses may be connected to or otherwise in communication with one another in a number of different manners, such as directly or indirectly via a wired or wireless network or the like.

FIG. 10 illustrates an apparatus 1000 according to some example implementations of the present disclosure. Generally, an apparatus of exemplary implementations of the present disclosure may comprise, include or be embodied in one or more fixed or portable electronic devices. Examples of suitable electronic devices include a smartphone, tablet computer, laptop computer, desktop computer, workstation computer, server computer or the like. The apparatus may include one or more of each of a number of components such as, for example, a processor 1002 (e.g., processor unit) connected to a memory 1004 (e.g., storage device).

The processor 1002 may be composed of one or more processors alone or in combination with one or more memories. The processor is generally any piece of computer hardware that is capable of processing information such as, for example, data, computer programs and/or other suitable electronic information. The processor is composed of a collection of electronic circuits some of which may be packaged as an integrated circuit or multiple interconnected integrated circuits (an integrated circuit at times more commonly referred to as a “chip”). The processor may be configured to execute computer programs, which may be stored onboard the processor or otherwise stored in the memory 1004 (of the same or another apparatus).

The processor 1002 may be a number of processors, a multi-core processor or some other type of processor, depending on the particular implementation. Further, the processor may be implemented using a number of heterogeneous processor systems in which a main processor is present with one or more secondary processors on a single chip. As another illustrative example, the processor may be a symmetric multi-processor system containing multiple processors of the same type. In yet another example, the processor may be embodied as or otherwise include one or more ASICs, FPGAs or the like. Thus, although the processor may be capable of executing a computer program to perform one or more functions, the processor of various examples may be capable of performing one or more functions without the aid of a computer program. In either instance, the processor may be appropriately programmed to perform functions or operations according to example implementations of the present disclosure.

The memory 1004 is generally any piece of computer hardware that is capable of storing information such as, for example, data, computer programs (e.g., computer-readable program code 1006) and/or other suitable information either on a temporary basis and/or a permanent basis. According to example implementations, this may include the modeling application 202 and the testing application 204. The memory may include volatile and/or non-volatile memory, and may be fixed or removable. Examples of suitable memory include random access memory (RAM), read-only memory (ROM), a hard drive, a flash memory, a thumb drive, a removable computer diskette, an optical disk, a magnetic tape or some combination of the above. Optical disks may include compact disk—read only memory (CD-ROM), compact disk—read/write (CD-R/W), DVD or the like. In various instances, the memory may be referred to as a computer-readable storage medium. The computer-readable storage medium is a non-transitory device capable of storing information, and is distinguishable from computer-readable transmission media such as electronic transitory signals capable of carrying information from one location to another. Computer-readable medium as described herein may generally refer to a computer-readable storage medium or computer-readable transmission medium.

In addition to the memory 1004, the processor 1002 may also be connected to one or more interfaces for displaying, transmitting and/or receiving information. The interfaces may include a communications interface 1008 (e.g., communications unit) and/or one or more user interfaces. The communications interface may be configured to transmit and/or receive information, such as to and/or from other apparatus(es), network(s) or the like. The communications interface may be configured to transmit and/or receive information by physical (wired) and/or wireless communications links. Examples of suitable communication interfaces include a network interface controller (NIC), wireless NIC (WNIC) or the like.

The user interfaces may include a display 1010 and/or one or more user input interfaces 1012 (e.g., input/output unit). The display may be configured to present or otherwise display information to a user, suitable examples of which include a liquid crystal display (LCD), light-emitting diode display (LED), plasma display panel (PDP) or the like. The user input interfaces may be wired or wireless, and may be configured to receive information from a user into the apparatus, such as for processing, storage and/or display. Suitable examples of user input interfaces include a microphone, image or video capture device, keyboard or keypad, joystick, touch-sensitive surface (separate from or integrated into a touchscreen), biometric sensor or the like. The user interfaces may further include one or more interfaces for communicating with peripherals such as printers, scanners or the like.

As indicated above, program code instructions may be stored in memory, and executed by processor that is thereby programmed, to implement functions of the systems, subsystems, tools and their respective elements described herein. As will be appreciated, any suitable program code instructions may be loaded onto a computer or other programmable apparatus from a computer-readable storage medium to produce a particular machine, such that the particular machine becomes a means for implementing the functions specified herein. These program code instructions may also be stored in a computer-readable storage medium that can direct a computer, processor or other programmable apparatus to function in a particular manner to thereby generate a particular machine or particular article of manufacture. The instructions stored in the computer-readable storage medium may produce an article of manufacture, where the article of manufacture becomes a means for implementing functions described herein. The program code instructions may be retrieved from a computer-readable storage medium and loaded into a computer, processor or other programmable apparatus to configure the computer, processor or other programmable apparatus to execute operations to be performed on or by the computer, processor or other programmable apparatus.

Retrieval, loading and execution of the program code instructions may be performed sequentially such that one instruction is retrieved, loaded and executed at a time. In some example implementations, retrieval, loading and/or execution may be performed in parallel such that multiple instructions are retrieved, loaded, and/or executed together. Execution of the program code instructions may produce a computer-implemented process such that the instructions executed by the computer, processor or other programmable apparatus provide operations for implementing functions described herein.

Execution of instructions by processor, or storage of instructions in a computer-readable storage medium, supports combinations of operations for performing the specified functions. In this manner, an apparatus 1000 may include processor 1002 and a computer-readable storage medium or memory 1004 coupled to the processor, where the processor is configured to execute computer-readable program code 1006 stored in the memory. It will also be understood that one or more functions, and combinations of functions, may be implemented by special purpose hardware-based computer systems and/or processor which perform the specified functions, or combinations of special purpose hardware and program code instructions.

As described herein, the present disclosure includes, without limitation, at least the following example implementations.

### EXAMPLE IMPLEMENTATION 1

An apparatus for testing designs of wiring harnesses, the apparatus comprising a processor and a memory storing executable instructions that, in response to execution by the processor, cause the apparatus to at least execute a modeling application to generate a virtual electrical system including virtual wiring harnesses that interconnect virtual modules of communications circuitry including telemetry and command modules, the virtual wiring harnesses having functionality equivalent to that of the designs of wiring harnesses, the virtual modules having signal sources, signal destinations and redistribution points therebetween, the virtual modules also having electrical connections to the signal sources, signal destinations and redistribution points, and the virtual wiring harnesses being connected to the electrical connections and thereby forming signal pathways through the virtual electrical system including at least the telemetry and command modules, each signal pathway being defined by respective electrical connections to a signal source, signal destination and any redistribution point therebetween, and by at least one of the virtual wiring harnesses connected to the respective electrical connections; and execute a testing application to test the signal pathways and thereby the virtual wiring harnesses, including for each signal pathway having thereon specific electrical connections to a signal source, signal destination and any redistribution point therebetween, the testing application being executed to at least: generate a simulated signal that is input to the specific electrical connection at the signal source and routed through the signal pathway to the specific electrical connection to the signal destination; verify receipt of the simulated signal by the specific electrical connections via the signal pathway; and in an instance in which receipt of the simulated signal is not verified, identify a particular electrical connection of the specific electrical connections at which an error occurred in the receipt of the simulated signal, and identify a particular virtual wiring harness and a particular virtual module respectively connected to and including the particular electrical connection, and wherein the testing application is executed to further generate a displayable output that identifies for each error, the particular electrical connection at which the error occurred, and the particular virtual wiring harness and the particular virtual module respectively connected to and including the particular electrical connection.

### EXAMPLE IMPLEMENTATION 2

The apparatus of any preceding or any subsequent example implementation, or any combination thereof, wherein the virtual modules include a virtual module with a redistribution point embodied as a switch with multiple inputs and a single output, each of the multiple inputs to the single output being on a separate one of the signal pathways.

### EXAMPLE IMPLEMENTATION 3

The apparatus of any preceding or any subsequent example implementation, or any combination thereof, wherein the virtual modules include a virtual module with a redistribution point embodied as a switch with a single input and multiple outputs, the signal input to each of the multiple outputs being on a separate one of the signal pathways.

### EXAMPLE IMPLEMENTATION 4

The apparatus of any preceding or any subsequent example implementation, or any combination thereof, wherein the apparatus being caused to execute the testing application to generate the displayable output includes being caused to execute the testing application to generate the displayable output that further includes for each error, routing data for the simulated signal that identifies one or more of the specific electrical connections at which the receipt of the simulated signal is verified.

### EXAMPLE IMPLEMENTATION 5

The apparatus of any preceding or any subsequent example implementation, or any combination thereof, wherein the memory stores executable instructions that, in response to execution by the processor and when the receipt of the simulated signal is not verified, cause the apparatus to further re-execute the modeling application to generate a modified virtual electrical system in which the particular virtual wiring harness has functionality equivalent to a modified design that corrects the error; and re-execute the testing application to test the signal pathways through the modified virtual electrical system.

### EXAMPLE IMPLEMENTATION 6

The apparatus of any preceding or any subsequent example implementation, or any combination thereof, wherein the apparatus being caused to execute the testing application includes being caused to execute the testing application to further transmit the displayable output to a visualization tool configured to display the virtual electrical system and identify thereon the particular electrical connection at which the error occurred, and the particular virtual wiring harness and the particular virtual module respectively connected to and including the particular electrical connection.

### EXAMPLE IMPLEMENTATION 7

The apparatus of any preceding or any subsequent example implementation, or any combination thereof, wherein the apparatus being caused to execute the testing application includes being caused to execute the testing application to generate the displayable output that in an instance in which receipt of the simulated signal by the specific electrical connections is verified, indicates the designs of wiring harnesses are validated for production of the wiring harnesses based thereon.

### EXAMPLE IMPLEMENTATION 8

The apparatus of any preceding or any subsequent example implementation, or any combination thereof, wherein the modeling application is implemented by a harness validation tool configured to create a directed graph that serves as the virtual electrical system, the directed graph including vertices and edges, each vertex representing virtual module with one or more electrical connections, and each edge representing a wire of a virtual wiring harness between electrical connections.

### EXAMPLE IMPLEMENTATION 9

The apparatus of any preceding or any subsequent example implementation, or any combination thereof, wherein the harness validation tool is configured to use the virtual modules to add multiple edges to the directed graph as well as routing electrical connections.

### EXAMPLE IMPLEMENTATION 10

The apparatus of any preceding or any subsequent example implementation, or any combination thereof, wherein the testing application is implemented by a harness validation tool configured to test the signal pathways according to a suite of test cases each of which is a representation of a signal sent through the system from a signal source.

### EXAMPLE IMPLEMENTATION 11

The apparatus of any preceding or any subsequent example implementation, or any combination thereof, wherein the suite of test cases is exported from a satellite systems engineering database (SSED).

### EXAMPLE IMPLEMENTATION 12

The apparatus of any preceding or any subsequent example implementation, or any combination thereof, wherein the harness validation tool being configured to test the signal pathways includes being configured to implement a recursive signal pathway traversal algorithm to determine all the wires of the virtual wiring harnesses traversed for a particular test case.

### EXAMPLE IMPLEMENTATION 13

A method of testing designs of wiring harnesses, the method comprising executing a modeling application to generate a virtual electrical system including virtual wiring harnesses that interconnect virtual modules of communications circuitry including telemetry and command modules, the virtual wiring harnesses having functionality equivalent to that of the designs of wiring harnesses, the virtual modules having signal sources, signal destinations and redistribution points therebetween, the virtual modules also having electrical connections to the signal sources, signal destinations and redistribution points, and the virtual wiring harnesses being connected to the electrical connections and thereby forming signal pathways through the virtual electrical system including at least the telemetry and command modules, each signal pathway being defined by respective electrical connections to a signal source, signal destination and any redistribution point therebetween, and by at least one of the virtual wiring harnesses connected to the respective electrical connections; and executing a testing application to test the signal pathways and thereby the virtual wiring harnesses, including for each signal pathway having thereon specific electrical connections to a signal source, signal destination and any redistribution point therebetween, the testing application at least: generating a simulated signal that is input to the specific electrical connection at the signal source and routed through the signal pathway to the specific electrical connection to the signal destination; verifying receipt of the simulated signal by the specific electrical connections via the signal pathway; and in an instance in which receipt of the simulated signal is not verified, identifying a particular electrical connection of the specific electrical connections at which an error occurred in the receipt of the simulated signal, and identifying a particular virtual wiring harness and a particular virtual module respectively connected to and including the particular electrical connection, and wherein the testing application is executed to further generate a displayable output that identifies for each error, the particular electrical connection at which the error occurred, and the particular virtual wiring harness and the particular virtual module respectively connected to and including the particular electrical connection.

### EXAMPLE IMPLEMENTATION 14

The method of any preceding or any subsequent example implementation, or any combination thereof, wherein the virtual modules include a virtual module with a redistribution point embodied as a switch with multiple inputs and a single output, each of the multiple inputs to the single output being on a separate one of the signal pathways.

### EXAMPLE IMPLEMENTATION 15

The method of any preceding or any subsequent example implementation, or any combination thereof, wherein the virtual modules include a virtual module with a redistribution point embodied as a switch with a single input and multiple outputs, the signal input to each of the multiple outputs being on a separate one of the signal pathways.

### EXAMPLE IMPLEMENTATION 16

The method of any preceding or any subsequent example implementation, or any combination thereof, wherein executing the testing application to generate the displayable output includes executing the testing application to generate the displayable output that further includes for each error, routing data for the simulated signal that identifies one or more of the specific electrical connections at which the receipt of the simulated signal is verified.

### EXAMPLE IMPLEMENTATION 17

The method of any preceding or any subsequent example implementation, or any combination thereof, wherein when the receipt of the simulated signal is not verified, the method further comprises re-executing the modeling application to generate a modified virtual electrical system in which the particular virtual wiring harness has functionality equivalent to a modified design that corrects the error; and re-executing the testing application to test the signal pathways through the modified virtual electrical system.

### EXAMPLE IMPLEMENTATION 18

The method of any preceding or any subsequent example implementation, or any combination thereof, wherein executing the testing application includes executing the testing application to further transmit the displayable output to a visualization tool configured to display the virtual electrical system and identify thereon the particular electrical connection at which the error occurred, and the particular virtual wiring harness and the particular virtual module respectively connected to and including the particular electrical connection.

### EXAMPLE IMPLEMENTATION 19

The method of any preceding or any subsequent example implementation, or any combination thereof, wherein executing the testing application includes executing the testing application to generate the displayable output that in an instance in which receipt of the simulated signal by the specific electrical connections is verified, indicates the designs of wiring harnesses are validated for production of the wiring harnesses based thereon.

### EXAMPLE IMPLEMENTATION 20

The method of any preceding or any subsequent example implementation, or any combination thereof, wherein the modeling application is implemented by a harness validation tool configured to create a directed graph that serves as the virtual electrical system, the directed graph including vertices and edges, each vertex representing virtual module with one or more electrical connections, and each edge representing a wire of a virtual wiring harness between electrical connections.

### EXAMPLE IMPLEMENTATION 21

The method of any preceding or any subsequent example implementation, or any combination thereof, wherein the harness validation tool is configured to use the virtual modules to add multiple edges to the directed graph as well as routing electrical connections.

### EXAMPLE IMPLEMENTATION 22

The method of any preceding or any subsequent example implementation, or any combination thereof, wherein the testing application is implemented by a harness validation tool configured to test the signal pathways according to a suite of test cases each of which is a representation of a signal sent through the system from a signal source.

### EXAMPLE IMPLEMENTATION 23

The method of any preceding or any subsequent example implementation, or any combination thereof, wherein the suite of test cases is exported from a satellite systems engineering database (SSED).

### EXAMPLE IMPLEMENTATION 24

The method of any preceding or any subsequent example implementation, or any combination thereof, wherein the harness validation tool being configured to test the signal pathways includes being configured to implement a recursive signal pathway traversal algorithm to determine all the wires of the virtual wiring harnesses traversed for a particular test case.

### EXAMPLE IMPLEMENTATION 25

A computer readable storage medium for testing designs of wiring harnesses, the computer-readable storage medium being non-transitory and having computer-readable program code portions stored therein that, in response to execution by a processor, cause an apparatus to at least execute a modeling application to generate a virtual electrical system including virtual wiring harnesses that interconnect virtual modules of communications circuitry including telemetry and command modules, the virtual wiring harnesses having functionality equivalent to that of the designs of wiring harnesses, the virtual modules having signal sources, signal destinations and redistribution points therebetween, the virtual modules also having electrical connections to the signal sources, signal destinations and redistribution points, and the virtual wiring harnesses being connected to the electrical connections and thereby forming signal pathways through the virtual electrical system including at least the telemetry and command modules, each signal pathway being defined by respective electrical connections to a signal source, signal destination and any redistribution point therebetween, and by at least one of the virtual wiring harnesses connected to the respective electrical connections; and execute a testing application to test the signal pathways and thereby the virtual wiring harnesses, including for each signal pathway having thereon specific electrical connections to a signal source, signal destination and any redistribution point therebetween, the testing application being executed to at least: generate a simulated signal that is input to the specific electrical connection at the signal source and routed through the signal pathway to the specific electrical connection to the signal destination; verify receipt of the simulated signal by the specific electrical connections via the signal pathway; and in an instance in which receipt of the simulated signal is not verified, identify a particular electrical connection of the specific electrical connections at which an error occurred in the receipt of the simulated signal, and identify a particular virtual wiring harness and a particular virtual module respectively connected to and including the particular electrical connection, and wherein the testing application is executed to further generate a displayable output that identifies for each error, the particular electrical connection at which the error occurred, and the particular virtual wiring harness and the particular virtual module respectively connected to and including the particular electrical connection.

### EXAMPLE IMPLEMENTATION 26

The computer readable storage medium of any preceding or any subsequent example implementation, or any combination thereof, wherein the virtual modules include a virtual module with a redistribution point embodied as a switch with multiple inputs and a single output, each of the multiple inputs to the single output being on a separate one of the signal pathways.

### EXAMPLE IMPLEMENTATION 27

The computer readable storage medium of any preceding or any subsequent example implementation, or any combination thereof, wherein the virtual modules include a virtual module with a redistribution point embodied as a switch with a single input and multiple outputs, the signal input to each of the multiple outputs being on a separate one of the signal pathways.

### EXAMPLE IMPLEMENTATION 28

The computer readable storage medium of any preceding or any subsequent example implementation, or any combination thereof, wherein the apparatus being caused to execute the testing application to generate the displayable output includes being caused to execute the testing application to generate the displayable output that further includes for each error, routing data for the simulated signal that identifies one or more of the specific electrical connections at which the receipt of the simulated signal is verified.

### EXAMPLE IMPLEMENTATION 29

The computer readable storage medium of any preceding or any subsequent example implementation, or any combination thereof, wherein the computer readable storage medium has computer-readable program code portions stored therein that, in response to execution by the processor and when the receipt of the simulated signal is not verified, cause the apparatus to further re-execute the modeling application to generate a modified virtual electrical system in which the particular virtual wiring harness has functionality equivalent to a modified design that corrects the error; and re-execute the testing application to test the signal pathways through the modified virtual electrical system.

### EXAMPLE IMPLEMENTATION 30

The computer readable storage medium of any preceding or any subsequent example implementation, or any combination thereof, wherein the apparatus being caused to execute the testing application includes being caused to execute the testing application to further transmit the displayable output to a visualization tool configured to display the virtual electrical system and identify thereon the particular electrical connection at which the error occurred, and the particular virtual wiring harness and the particular virtual module respectively connected to and including the particular electrical connection.

### EXAMPLE IMPLEMENTATION 31

The computer readable storage medium of any preceding or any subsequent example implementation, or any combination thereof, wherein the apparatus being caused to execute the testing application includes being caused to execute the testing application to generate the displayable output that in an instance in which receipt of the simulated signal by the specific electrical connections is verified, indicates the designs of wiring harnesses are validated for production of the wiring harnesses based thereon.

### EXAMPLE IMPLEMENTATION 32

The computer readable storage medium of any preceding or any subsequent example implementation, or any combination thereof, wherein the modeling application is implemented by a harness validation tool configured to create a directed graph that serves as the virtual electrical system, the directed graph including vertices and edges, each vertex representing virtual module with one or more electrical connections, and each edge representing a wire of a virtual wiring harness between electrical connections.

### EXAMPLE IMPLEMENTATION 33

The computer readable storage medium of any preceding or any subsequent example implementation, or any combination thereof, wherein the harness validation tool is configured to use the virtual modules to add multiple edges to the directed graph as well as routing electrical connections.

### EXAMPLE IMPLEMENTATION 34

The computer readable storage medium of any preceding or any subsequent example implementation, or any combination thereof, wherein the testing application is implemented by a harness validation tool configured to test the signal pathways according to a suite of test cases each of which is a representation of a signal sent through the system from a signal source.

### EXAMPLE IMPLEMENTATION 35

The computer readable storage medium of any preceding or any subsequent example implementation, or any combination thereof, wherein the suite of test cases is exported from a satellite systems engineering database (SSED).

### EXAMPLE IMPLEMENTATION 36

The computer readable storage medium of any preceding or any subsequent example implementation, or any combination thereof, wherein the harness validation tool being configured to test the signal pathways includes being configured to implement a recursive signal pathway traversal algorithm to determine all the wires of the virtual wiring harnesses traversed for a particular test case.

As explained above, the present disclosure includes any combination of two, three, four or more features or elements set forth in this disclosure, regardless of whether such features or elements are expressly combined or otherwise recited in a specific example implementation described herein. This disclosure is intended to be read holistically such that any separable features or elements of the disclosure, in any of its aspects and example implementations, should be viewed as combinable, unless the context of the disclosure clearly dictates otherwise.

Many modifications and other implementations of the disclosure set forth herein will come to mind to one skilled in the art to which the disclosure pertains having the benefit of the teachings presented in the foregoing description and the associated drawings. Therefore, it is to be understood that the disclosure is not to be limited to the specific implementations disclosed and that modifications and other implementations are intended to be included within the scope of the appended claims. Moreover, although the foregoing description and the associated drawings describe example implementations in the context of certain example combinations of elements and/or functions, it should be appreciated that different combinations of elements and/or functions may be provided by alternative implementations without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. An apparatus for testing designs of wiring harnesses, the apparatus comprising a processor and a memory storing executable instructions that, in response to execution by the processor, cause the apparatus to at least:
execute a modeling application to generate a virtual electrical system including virtual wiring harnesses that interconnect virtual modules of communications circuitry including telemetry and command modules, the virtual wiring harnesses having functionality equivalent to that of the designs of wiring harnesses, the virtual modules having signal sources, signal destinations and redistribution points therebetween, the virtual modules also having electrical connections to the signal sources, signal destinations and redistribution points, and the virtual wiring harnesses being connected to the electrical connections and thereby forming signal pathways through the virtual electrical system including at least the telemetry and command modules, each signal pathway being defined by respective electrical connections to a signal source, signal destination and any redistribution point therebetween, and by at least one of the virtual wiring harnesses connected to the respective electrical connections; and
execute a testing application to test the signal pathways and thereby the virtual wiring harnesses, including for each signal pathway having thereon specific electrical connections to a signal source, signal destination and any redistribution point therebetween, the testing application being executed to at least:
generate a simulated signal that is input to the specific electrical connection at the signal source and routed through the signal pathway to the specific electrical connection to the signal destination;
verify receipt of the simulated signal by the specific electrical connections via the signal pathway; and in an instance in which receipt of the simulated signal is not verified,
identify a particular electrical connection of the specific electrical connections at which an error occurred in the receipt of the simulated signal, and identify a particular virtual wiring harness and a particular virtual module respectively connected to and including the particular electrical connection, and
wherein the testing application is executed to further generate a displayable output that identifies for each error, the particular electrical connection at which the error occurred, and the particular virtual wiring harness and the particular virtual module respectively connected to and including the particular electrical connection.

2. The apparatus of claim 1, wherein the virtual modules include a virtual module with a redistribution point embodied as a switch with multiple inputs and a single output, each of the multiple inputs to the single output being on a separate one of the signal pathways.

3. The apparatus of claim 1, wherein the virtual modules include a virtual module with a redistribution point embodied as a switch with a single input and multiple outputs, the signal input to each of the multiple outputs being on a separate one of the signal pathways.

4. The apparatus of claim 1, wherein the apparatus being caused to execute the testing application to generate the displayable output includes being caused to execute the testing application to generate the displayable output that further includes for each error, routing data for the simulated signal that identifies one or more of the specific electrical connections at which the receipt of the simulated signal is verified.

5. The apparatus of claim 1, wherein the memory stores executable instructions that, in response to execution by the processor and when the receipt of the simulated signal is not verified, cause the apparatus to further:
re-execute the modeling application to generate a modified virtual electrical system in which the particular virtual wiring harness has functionality equivalent to a modified design that corrects the error; and
re-execute the testing application to test the signal pathways through the modified virtual electrical system.

6. The apparatus of claim 1, wherein the apparatus being caused to execute the testing application includes being caused to execute the testing application to further transmit the displayable output to a visualization tool configured to display the virtual electrical system and identify thereon the particular electrical connection at which the error occurred, and the particular virtual wiring harness and the particular virtual module respectively connected to and including the particular electrical connection.

7. The apparatus of claim 1, wherein the apparatus being caused to execute the testing application includes being caused to execute the testing application to generate the displayable output that in an instance in which receipt of the simulated signal by the specific electrical connections is verified, indicates the designs of wiring harnesses are validated for production of the wiring harnesses based thereon.

8. A method of testing designs of wiring harnesses, the method comprising:
executing a modeling application to generate a virtual electrical system including virtual wiring harnesses that interconnect virtual modules of communications circuitry including telemetry and command modules, the virtual wiring harnesses having functionality equivalent to that of the designs of wiring harnesses, the virtual modules having signal sources, signal destinations and redistribution points therebetween, the virtual modules also having electrical connections to the signal sources, signal destinations and redistribution points, and the virtual wiring harnesses being connected to the electrical connections and thereby forming signal pathways through the virtual electrical system including at least the telemetry and command modules, each signal pathway being defined by respective electrical connections to a signal source, signal destination and any redistribution point therebetween, and by at least one of the virtual wiring harnesses connected to the respective electrical connections; and
executing a testing application to test the signal pathways and thereby the virtual wiring harnesses, including for each signal pathway having thereon specific electrical connections to a signal source, signal destination and any redistribution point therebetween, the testing application at least:
generating a simulated signal that is input to the specific electrical connection at the signal source and routed through the signal pathway to the specific electrical connection to the signal destination;
verifying receipt of the simulated signal by the specific electrical connections via the signal pathway; and in an instance in which receipt of the simulated signal is not verified,
identifying a particular electrical connection of the specific electrical connections at which an error occurred in the receipt of the simulated signal, and identifying a particular virtual wiring harness and a particular virtual module respectively connected to and including the particular electrical connection, and
wherein the testing application is executed to further generate a displayable output that identifies for each error, the particular electrical connection at which the error occurred, and the particular virtual wiring harness and the particular virtual module respectively connected to and including the particular electrical connection.

9. The method of claim 8, wherein the virtual modules include a virtual module with a redistribution point embodied as a switch with multiple inputs and a single output, each of the multiple inputs to the single output being on a separate one of the signal pathways.

10. The method of claim 8, wherein the virtual modules include a virtual module with a redistribution point embodied as a switch with a single input and multiple outputs, the signal input to each of the multiple outputs being on a separate one of the signal pathways.

11. The method of claim 8, wherein executing the testing application to generate the displayable output includes executing the testing application to generate the displayable output that further includes for each error, routing data for the simulated signal that identifies one or more of the specific electrical connections at which the receipt of the simulated signal is verified.

12. The method of claim 8, wherein when the receipt of the simulated signal is not verified, the method further comprises:
re-executing the modeling application to generate a modified virtual electrical system in which the particular virtual wiring harness has functionality equivalent to a modified design that corrects the error; and
re-executing the testing application to test the signal pathways through the modified virtual electrical system.

13. The method of claim 8, wherein executing the testing application includes executing the testing application to further transmit the displayable output to a visualization tool configured to display the virtual electrical system and identify thereon the particular electrical connection at which the error occurred, and the particular virtual wiring harness and the particular virtual module respectively connected to and including the particular electrical connection.

14. The method of claim 8, wherein executing the testing application includes executing the testing application to generate the displayable output that in an instance in which receipt of the simulated signal by the specific electrical connections is verified, indicates the designs of wiring harnesses are validated for production of the wiring harnesses based thereon.

15. A computer readable storage medium for testing designs of wiring harnesses, the computer-readable storage medium being non-transitory and having computer-readable program code portions stored therein that, in response to execution by a processor, cause an apparatus to at least:
execute a modeling application to generate a virtual electrical system including virtual wiring harnesses that interconnect virtual modules of communications circuitry including telemetry and command modules, the virtual wiring harnesses having functionality equivalent to that of the designs of wiring harnesses, the virtual modules having signal sources, signal destinations and redistribution points therebetween, the virtual modules also having electrical connections to the signal sources, signal destinations and redistribution points, and the virtual wiring harnesses being connected to the electrical connections and thereby forming signal pathways through the virtual electrical system including at least the telemetry and command modules, each signal pathway being defined by respective electrical connections to a signal source, signal destination and any redistribution point therebetween, and by at least one of the virtual wiring harnesses connected to the respective electrical connections; and
execute a testing application to test the signal pathways and thereby the virtual wiring harnesses, including for each signal pathway having thereon specific electrical connections to a signal source, signal destination and any redistribution point therebetween, the testing application being executed to at least:
generate a simulated signal that is input to the specific electrical connection at the signal source and routed through the signal pathway to the specific electrical connection to the signal destination;
verify receipt of the simulated signal by the specific electrical connections via the signal pathway; and in an instance in which receipt of the simulated signal is not verified,
identify a particular electrical connection of the specific electrical connections at which an error occurred in the receipt of the simulated signal, and identify a particular virtual wiring harness and a particular virtual module respectively connected to and including the particular electrical connection, and
wherein the testing application is executed to further generate a displayable output that identifies for each error, the particular electrical connection at which the error occurred, and the particular virtual wiring harness and the particular virtual module respectively connected to and including the particular electrical connection.

16. The computer readable storage medium of claim 15, wherein the virtual modules include a virtual module with a redistribution point embodied as a switch with multiple inputs and a single output, each of the multiple inputs to the single output being on a separate one of the signal pathways.

17. The computer readable storage medium of claim 15, wherein the virtual modules include a virtual module with a redistribution point embodied as a switch with a single input and multiple outputs, the signal input to each of the multiple outputs being on a separate one of the signal pathways.

18. The computer readable storage medium of claim 15, wherein the apparatus being caused to execute the testing application to generate the displayable output includes being caused to execute the testing application to generate the displayable output that further includes for each error, routing data for the simulated signal that identifies one or more of the specific electrical connections at which the receipt of the simulated signal is verified.

19. The computer readable storage medium of claim 15, wherein the computer readable storage medium has computer-readable program code portions stored therein that, in response to execution by the processor and when the receipt of the simulated signal is not verified, cause the apparatus to further:
re-execute the modeling application to generate a modified virtual electrical system in which the particular virtual wiring harness has functionality equivalent to a modified design that corrects the error; and
re-execute the testing application to test the signal pathways through the modified virtual electrical system.

20. The computer readable storage medium of claim 15, wherein the apparatus being caused to execute the testing application includes being caused to execute the testing application to further transmit the displayable output to a visualization tool configured to display the virtual electrical system and identify thereon the particular electrical connection at which the error occurred, and the particular virtual wiring harness and the particular virtual module respectively connected to and including the particular electrical connection.

21. The computer readable storage medium of claim 15, wherein the apparatus being caused to execute the testing application includes being caused to execute the testing application to generate the displayable output that in an instance in which receipt of the simulated signal by the specific electrical connections is verified, indicates the designs of wiring harnesses are validated for production of the wiring harnesses based thereon.
